(19) United States
(12) Patent Application Publication
(10) Pub. No.: US 2022/0363947 A1
(43) Pub. Date: Nov. 17, 2022

(54) Packaging Material And Methods Of Manufacture

(71) Applicant: Applied Materials, Inc., Santa Clara, CA (US)

(72) Inventors: Vibhas Singh, San Jose, CA (US); Wen-Hao Wu, San Jose, CA (US); Jrjyan Jerry Chen, Campbell, CA (US); Soo Young Choi, Fremont, CA (US)

(73) Assignee: Applied Materials, Inc., Santa Clara, CA (US)

(21) Appl. No.: 17/741,658

(22) Filed: May 11, 2022

Related U.S. Application Data
(60) Provisional application No. 63/189,456, filed on May 17, 2021.

(51) Int. Cl. C09D 183/08; B65D 25/34; C23C 14/00; C23C 14/54

(52) U.S. Cl. CPC C09D 183/08; B65D 25/34; C23C 14/0057; C23C 14/542

(57) ABSTRACT

Packaging materials and methods of manufacture are disclosed. The packaging material comprises a substrate surface and film coating selected from the group consisting of an elastomer, a polymer, an inorganic material and combinations thereof. The film coating includes a first layer and a second layer, the first layer deposited on the second layer. The first layer has a formula of SiOₓN_{y}C_{z}, where x is in a range from 1.9 to 2.15, y is in a range from 0.01 to 0.08, and z is in a range from 0.10 to 0.40.

### CROSS-REFERENCE TO RELATED APPLICATIONS

This application claims priority to U.S. Provisional Application No. 63/189,456, filed May 17, 2021, the entire disclosure of which is hereby incorporated by reference herein.

### TECHNICAL FIELD

Embodiments of the disclosure relate to packaging material, in particular packaging material including a film coating and methods of manufacture.

### BACKGROUND

Many of pharmaceutical products, especially parenteral drugs, need glass/plastic containers and/or elastomeric seals and closures. These pharmaceutical packaging materials are less than ideal for a variety of reasons that lead to loss of drug or loss of its efficacy, contamination/particles leading to immunogenicity problems and sometimes drug recalls. The most common problems with the glass containers are breakage, delamination, protein agglomeration (especially with large molecules/biologics), and metal leaching. In addition, plastic containers have a poor barrier performance that leads to drug dilution or loss of efficacy or shelf-life issues.

Elastomers suffer from a separate set of problems and are considered the weakest link in the moisture/oxygen ingress inside a drug. As a very different material than glass/plastic, elastomers lead to stronger concerns around undesired extractables and leachables in the drug formulation. Some of the elastomeric components need a silicone oil for lubrication which causes particles issues and leads to design control problems in devices such as pre-filled syringes and auto-injectors.

Accordingly, there is a need for pharmaceutical packaging materials that exhibit one or more of high inertness, reduced extractability, reduced leachability or high lubricity.

### SUMMARY

One or more embodiments of the disclosure are directed to a packaging material. In some embodiments, the packaging material comprises a substrate including a substrate surface, the substrate surface comprising a material selected from the group consisting of an elastomer, a polymer, an inorganic material and combinations thereof, and a film coating comprising a first layer on the substrate surface and a second layer on the first layer, wherein the first layer comprises a first material having a formula of SiOₓN_{y}C_{z}, where x is in a range from 1.9 to 2.15, y is in a range from 0.01 to 0.08, and z is in a range from 0.10 to 0.40, and the second layer comprises a second material having a formula of SiOₓN_{y}C_{z}, where x is in a range from 1.30 to 1.50, y is in a range from 0.05 to 0.20, and z is in a range from 1 to 2.

Another aspect of the disclosure is directed to a method of depositing a film coating on a packaging material comprising a substrate surface. In some embodiments, the method comprises exposing the substrate surface to a first precursor to deposit a first layer on the substrate surface, optionally purging the first precursor, and exposing the first layer to a second precursor to deposit a second layer on the first layer. In some embodiments, the first layer has a formula of SiOₓN_{y}C_{z}, where x is in a range from 1.9 to 2.15, y is in a range from 0.01 to 0.08, and z is in a range from 0.10 to 0.40. In some embodiments, the second layer has a formula of SiOₓN_{y}C_{z}, where x is in a range from 1.30 to 1.50, y is in a range from 0.05 to 0.20, and z is in a range from 1.0 to 2.0. In some embodiments, each of the first precursor and the second precursor independently comprises a silicon-containing precursor, a nitrogen-containing precursor, a hydrogen-containing precursor, an oxygen-containing precursor, a carbon-containing precursor, or combinations thereof.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A through 1C show a schematic of packaging material according to one or more embodiments of the disclosure; and

FIG. 2 is a flowchart showing a method according to an embodiment of the disclosure.

### DETAILED DESCRIPTION

Before describing several exemplary embodiments of the disclosure, it is to be understood that the embodiments are not limited to the details of construction or process steps set forth in the following description. Additional embodiments may be contemplated without departing from the scope of the disclosure.

Embodiments directed to a packaging material and processes of making the packaging material are disclosed herein. According to one or more embodiments, the phrase “packaging material” includes, but is not limited to, a vial, a syringe, a bottle, a cartridge, an ampoule, an injection pen, a patch, a blister pack, and an intravenous infusion bag. In some embodiments, the packaging material comprises a substrate including a substrate surface and a film coating on the substrate surface. The film coating advantageously improves one or more properties of the packaging material. The one or more properties include, but are not limited to, high inertness, reduced extractability, reduced leachability or high lubricity compared to a packaging material that does not have a film coating. In one or more embodiments, the packaging material is used in pharmaceutical and medical applications.

The term “substrate” or “substrate surface”, as used herein, refers to any portion of a substrate or portion of a material surface formed on a substrate upon which film processing is performed. For example, a substrate surface on which processing can be performed includes materials such as a metal, metal alloy, metal nitride, inorganic material, plastic, polymer, elastomer, combinations thereof and any other materials suitable for packaging. In some embodiments, the plastic material includes, but is not limited to, polyethylene terephthalate (PET) or polyethylene naphthalate (PEN). In some embodiments, the polymer material comprises a hydrocarbon compound having a formula of CₐH_{b}O_{c}, where each of a, b and c is an independent integer. In some embodiments, the hydrocarbon material comprises polyacrylate, parylene, polyimides, polytetrafluoroethylene, copolymer of fluorinated ethylene propylene, perfluoroalkoxy copolymer resin, copolymer of ethylene and tetrafluoroethylene, parylene or other suitable polymeric material. In some embodiments, the inorganic material comprises glass, quartz, silicon dioxide (SiO₂), silicon nitride (SiN), or silicon oxynitride (SiON). In one or more embodiments, the elastomer comprises cyclic olefin polymer, cyclic olefin copolymer, polypropylene, polyester, polyethylene terephthalate, butyl rubber or combinations thereof.

In some embodiments, the film coating is flexible. As used herein, the term “flexible” is used interchangeably to mean a substance with a species capable of bending or twisting without breaking.

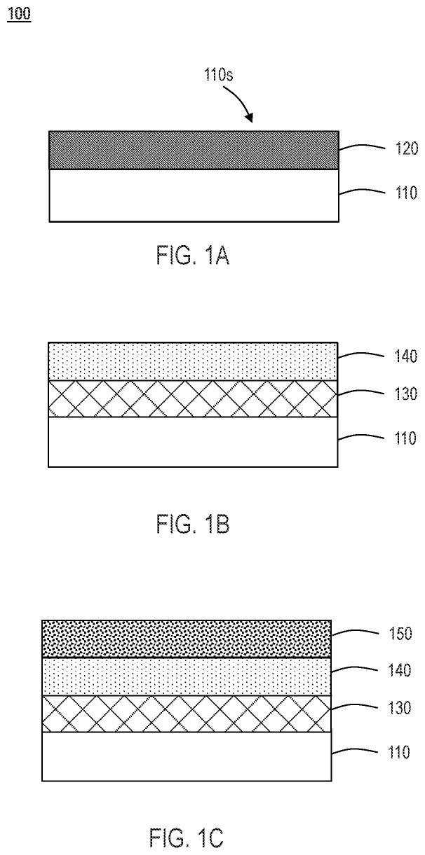

In one or more embodiments, the film coating comprises at least one layer. FIG. 1A illustrates a cross-sectional view of the packaging material 100 comprising a substrate 110 with a substrate surface 110s and a film coating 120. In some embodiments, the film coating 120 comprises a plurality of layers. In some embodiments, the plurality of layers is stacked on the substrate 110. In some embodiments, the plurality of layers comprises at least two layers. In some embodiments, the at least two layers further comprise a third layer. In some embodiments, all of the plurality of layers comprise the same material. In some embodiments, all of the plurality of layers are not the same material. In some embodiments, at least one of the plurality of layers is a different material than the remaining layer(s) material.

In one or more embodiments, the plurality of layers comprises a first layer and a second layer. In some embodiments, the first layer and the second layer are not the same material. In other embodiments, the first layer and the second layer comprises different materials. In some embodiments, the first layer is sandwiched between the second layer and the substrate 110. In some embodiments, the first layer and the second layer are stacked on the substrate 110. FIG. 1B illustrates a cross-sectional view of the packaging material 100 comprising the substrate 110, a first layer 130 and a second layer 140, wherein the first layer 130 is sandwiched between the substrate 110 and the second layer 140. In some embodiments, the first layer 130 is different than the second layer 140. In some embodiments, the first layer 130 promotes adhesion. In some embodiments, the second layer 140 acts as a barrier. In some embodiments, the second layer 140 is inert. In some embodiments, the second layer acts as a lubricant.

FIG. 1C illustrates a cross-sectional view of the packaging material 100 comprising the substrate 110, the first layer 130, the second layer 140 and a third layer 150, wherein the first layer 130 is sandwiched between the substrate 110 and the second layer 140, the second layer 140 is sandwiched between the first layer 130 and the third layer 150, and the first layer 130 and the second layer 140 are sandwiched between the substrate 110 and the third layer 150. In some embodiments, at least one of the first layer 130, the second layer 140 and the third layer 150 are stacked on the substrate 110 and each layer is different than the remaining layers. In other embodiments, each of the first layer 130, the second layer 140 and the third layer 150 comprises the same material. In some embodiments, the first layer 130 promotes adhesion. In some embodiments, the second layer 140 acts as a barrier. In some embodiments, the second layer 140 is inert. In some embodiments, the third layer 150 acts as a lubricant.

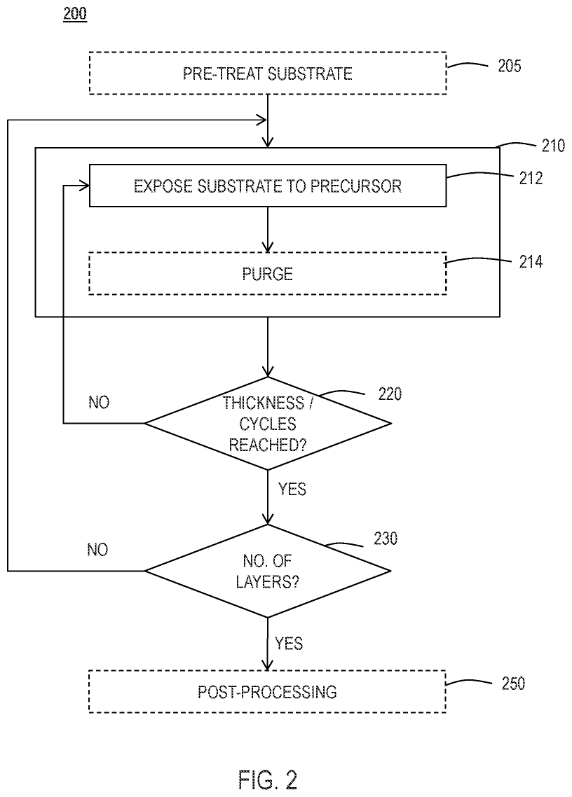

One aspect of the disclosure is directed to methods of depositing the film coating 120 on the substrate 110. FIG. 2 illustrates an exemplary embodiment of a method 200 of depositing the film coating 120 on the packaging material 100. In some embodiments, the method 200 includes an optional pretreatment operation 205. In one or more embodiments, the substrate 110 is optionally exposed to a pretreatment process before depositing the film coating 120 on the packaging material 100. In some embodiments, the pretreatment process includes, but is not limited to, pre-heating, cleaning, soaking, native oxide removal, polishing, etching, reducing, oxidizing, hydroxylating, annealing, UV curing, e-beam curing, baking, and/or depositing an adhesion layer. In addition to depositing and/or processing a film coating 120 directly on the substrate 100 itself (or a substrate surface 110s), in the present disclosure, any of the film coating processing steps disclosed herein may also be performed on an underlayer formed on the substrate 100 (or a substrate surface 110s) as disclosed in more detail below, and the term “substrate surface” is intended to include such underlayer as the context indicates. Thus, for example, where a film coating/layer or partial film coating/layer has been deposited onto a substrate surface, the exposed surface of the newly deposited film coating/layer becomes the substrate 110 (or substrate surface 110s).

According to one or more embodiments, the term “on” with respect to a film coating or a layer of a film coating includes the layer being directly deposited on a surface, for example, a substrate surface, as well as there being one or more underlayers between the layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

At process operation 210, the method 200 comprises two sub-processes. It is appreciated that more or fewer than two sub-processes can be included in the process operation 210 and the disclosure is not limited to the process illustrated. In some embodiments, the process operation 210 is performed to deposit the film coating on the substrate 110 (or substrate surface 110s). In some embodiments, the process operation 210 comprises exposing the substrate 110 to a precursor and optionally purging the precursor.

As used in this specification and the appended claims, the terms “reactive compound”, “reactive gas”, “reactive species”, “precursor”, “process gas”, “deposition precursor” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to two or more reactive compounds which are introduced into a processing region.

In some embodiments, the precursor comprises silicon-containing precursors, nitrogen-containing precursors, hydrogen-containing precursors, oxygen-containing precursors, carbon-containing precursors, or combinations thereof. The various silicon-containing precursors, nitrogen-containing precursors, hydrogen-containing precursors, oxygen-containing precursors, carbon-containing precursors, and combinations described in this paragraph can be used in the formation of any of the various layers (e.g., first layer, second layer, third layer, fourth layer, fifth layer) described herein. In some embodiments, the silicon-containing precursors comprise silane (SiH₄), SiF₄, Si₂H₆, or combinations thereof. In some embodiments, the silicon-containing precursors comprise silane (SiH₄), SiF₄, Si₂H₆, or combinations thereof. In some embodiments, the nitrogen-containing precursor comprises SiNₓ, where x is a positive integer. In some embodiments, the nitrogen-containing precursor comprises NH₃, N₂O, NO, N₂, or combinations thereof. In some embodiments, the hydrogen-containing precursor comprises H₂ or any of the nitrogen-containing precursors, silicon-containing precursors and organic carbon-containing precursors that contain hydrogen. In some embodiments, the oxygen-containing precursor comprises oxygen (O₂), carbon dioxide or combinations thereof. In some embodiments, the carbon-containing precursor comprises organic carbon-containing compounds. In some embodiments, the organic carbon-containing compounds comprise aliphatic organic compounds, cyclic organic compounds, or combinations thereof. Aliphatic organic compounds have linear or branched structures comprising one or more carbon atoms. Organic carbon-containing compounds contain carbon atoms in organic groups. Organic groups may include alkyl, alkenyl, alkynyl, cyclohexenyl, and aryl groups in addition to functional derivatives thereof. In some embodiments, the carbon-containing precursor has a formula of CₓH_{y}, where x is in a range from 1 to 8 and y is in a range from 2 to 8. In some embodiments, the carbon-containing precursor comprises acetylene (C₂H₂), ethane (C₂H₆), ethene (C₂H₄), methane (CH₄), propylene (C₃H₆), propyne (C₃H₄), propane (C₃H₈), butane (C₄H₁₀), butylene (C₄H₈), butadiene (C₄H₆), benzene (C₆H₆), toluene (C₇H₃), and hexamethyldisiloxane (C₆H₁₈OSi₂), or combinations thereof.

In some embodiments, as illustrated in process operation 212, the substrate 110 (or substrate surface) is exposed to the precursors for depositing the various layers of the film coating. In some embodiments, the film coating 120 comprises a material having a formula of SiH_{w}OₓN_{y}C_{z}, where each of w, x, y and z independently has a value in a range from 0.0 to 2.5. In some embodiments, w is in a range from 0.0 to 1.2, from 0.0 to 1.0, from 0.0 to 0.8, from 0.0 to 0.6, from 0.0 to 0.4, from 0.0 to 0.2, from 0.2 to 1.2, from 0.2 to 1.0, from 0.2 to 0.8, from 0.2 to 0.6, from 0.2 to 0.4, from 0.4 to 1.2, from 0.4 to 1.0, from 0.4 to 0.8, from 0.4 to 0.6, from 0.6 to 1.2, from 0.6 to 1.0, from 0.6 to 0.8, from 0.8 to 1.2, from 0.8 to 1.0 or from 1.0 to 1.2. In some embodiments, x is in a range from 0.0 to 2.5, from 0.0 to 2.0, from 0.0 to 1.5, from 0.0 to 1.0, from 0.0 to 0.5, from 0.5 to 2.5, from 0.5 to 2.0, from 0.5 to 1.5, from 0.5 to 1.0, from 1.0 to 2.5, from 1.0 to 2.0, from 1.0 to 1.5, from 1.5 to 2.5, from 1.5 to 2.0, or from 2.0 to 2.5. In some embodiments, y is in a range from 0.0 to 1.0, from 0.0 to 0.8, from 0.0 to 0.6, from 0.0 to 0.4, from 0.0 to 0.2, from 0.2 to 1.0, from 0.2 to 0.8, from 0.2 to 0.6, from 0.2 to 0.4, from 0.4 to 1.0, from 0.4 to 0.8, from 0.4 to 0.6, from 0.6 to 1.0, from 0.6 to 0.8, or from 0.8 to 1.0. In some embodiments, z is in a range from 0.0 to 2.0, from 0.0 to 1.6, from 0.0 to 1.2, from 0.0 to 0.8, from 0.0 to 0.4, from 0.4 to 2.0, from 0.4 to 1.6, from 0.4 to 1.2, from 0.4 to 0.8, from 0.8 to 2.0, from 0.8 to 1.6, from 0.8 to 1.2, from 1.2 to 2.0, from 1.2 to 1.6, or from 1.6 to 2.0.

In some embodiments, the film coating 120 comprises a material having a formula of SiOₓN_{y}C_{z}, where x is in a range from 0.6 to 2.15, y is in a range from 0.0 to 0.2, and z is in a range from 0.0 to 2.0. In some embodiments, the film coating 120 is an organic rich film coating. In some embodiments, the organic rich film coating comprises a material having a formula of SiOₓN_{y}C_{z}, where x is in a range from 0.6 to 2.15, y is in a range from 0.0 to 0.2, and z is in a range from 0.50 to 2.00. In some embodiments, the film coating 120 is an inorganic rich film. In some embodiments, the inorganic rich film coating comprises a material having a formula of SiOₓN_{y}C_{z}, where x is in a range from 0.6 to 2.15, y is in a range from 0.0 to 0.2, and z is in a range from 0.00 to 0.50.

In some embodiments, the film coating 120 comprises a material having a formula of SiH_{w}OₓN_{y}, where w is in a range from 0.0 to 1.2, x is in a range from 0.0 to 2.5, and y is in a range from 0.0 to 1.0.

In some embodiments, the first layer 130 comprises a first material having a formula of SiOₓN_{y}C_{z}, where x is in a range from 1.9 to 2.15, from 1.9 to 2.10, from 1.9 to 2.05, from 1.9 to 2.00, from 1.9 to 1.95, from 1.9 to 2.15, from 1.95 to 2.15, from 1.95 to 2.10, from 1.95 to 2.05, from 1.95 to 2.00, from 2.00 to 2.15, from 2.00 to 2.10, from 2.00 to 2.05, from 2.05 to 2.15, from 2.05 to 2.10, or from 2.10 to 2.15, y is in a range from 0.01 to 0.08, from 0.01 to 0.06, from 0.01 to 0.04, from 0.01 to 0.02, from 0.02 to 0.08, from 0.02 to 0.06, from 0.02 to 0.04, from 0.04 to 0.08, from 0.04 to 0.06, or from 0.06 to 0.08, and z is in a range from 0.10 to 0.40, from 0.10 to 0.30, from 0.10 to 0.20, from 0.20 to 0.40, from 0.20 to 0.30, or from 0.30 to 0.40.

In some embodiments, the second layer 140 comprises a second material having a formula of SiOₓN_{y}C_{z}, where x is in a range from 1.30 to 1.50, from 1.30 to 1.45, from 1.30 to 1.40, from 1.30 to 1.35, from 1.35 to 1.50, from 1.35 to 1.45, from 1.35 to 1.40, from 1.40 to 1.50, from 1.40 to 1.45, or from 1.45 to 1.50, y is in a range from 0.05 to 0.20, from 0.05 to 0.15, from 0.05 to 0.10, from 0.10 to 0.20, from 0.10 to 0.15, or from 0.15 to 0.20, and z is in a range from 1.0 to 2.0, from 1.0 to 1.8, from 1.0 to 1.6, from 1.0 to 1.4, from 1.0 to 1.2, from 1.2 to 2.0, from 1.2 to 1.8, from 1.2 to 1.6, from 1.2 to 1.4, from 1.4 to 2.0, from 1.4 to 1.8, from 1.4 to 1.6, from 1.6 to 2.0, from 1.6 to 1.8, or from 1.8 to 2.0.

In some embodiments, the third layer 150 comprises a material having a formula of SiH_{w}OₓN_{y}, where w is in a range from 0.01 to 1.10, from 0.01 to 1.05, from 0.01 to 1.00, from 0.01 to 0.50, from 0.01 to 0.10, from 0.01 to 0.05, from 0.05 to 1.10, from 0.05 to 1.05, from 0.05 to 1.00, from 0.05 to 0.50, from 0.05 to 0.10, from 0.10 to 1.10, from 0.10 to 1.05, from 0.10 to 1.00, from 0.10 to 0.50, from 0.50 to 1.10, from 0.50 to 1.05, from 0.50 to 1.00, from 1.00 to 1.10, from 1.00 to 1.05, or from 1.05 to 1.10, x is in a range from 0.01 to 2.30, from 0.01 to 2.00, from 0.01 to 1.50, from 0.01 to 1.00, from 0.01 to 0.50, from 0.01 to 0.10, from 0.10 to 2.30, from 0.10 to 2.00, from 0.10 to 1.50, from 0.10 to 1.00, from 0.10 to 0.50, from 0.50 to 2.30, from 0.50 to 2.00, from 0.50 to 1.50, from 0.50 to 1.00, from 1.00 to 2.30, from 1.00 to 2.00, from 1.00 to 1.50, from 1.50 to 2.30, from 1.50 to 2.00, from 2.00 to 2.30, and y is in a range from 0.01 to 1.0, from 0.01 to 0.5, from 0.01 to 0.1, from 0.01 to 0.05, from 0.05 to 1.0, from 0.05 to 0.5, from 0.05 to 0.1, from 0.1 to 1.0, from 0.1 to 0.5 or from 0.5 to 1.0.

In some embodiments, the film coating 120 comprises one or more additional layers (e.g., a fourth layer and a fifth layer) between the second layer 140 and the third layer 150. In some embodiments, the one or more additional layers independently has a thickness in a range from 1 nm to 100 nm. In one or more embodiments, the one or more additional layers independently comprise a formula of SiOₓN_{y}C_{z}, where x is in a range from 1.30 to 1.50, y is in a range from 0.05 to 0.20, and z is in a range from 1 to 2. In some embodiments, the one or more additional layers independently comprise a formula of SiH_{w}OₓN_{y}, where w is in a range from 0.01 to 1.1, x is in a range from 0.01 to 2.3, and y is in a range from 0.01 to 1.0.

In some embodiments, the precursor comprises one or more of a first precursor, a second precursor, and a third precursor. In some embodiments, the first precursor comprises one or more of the silicon-containing precursors, the nitrogen-containing precursor, the hydrogen-containing precursors, the oxygen-containing precursors, and the carbon-containing precursors described herein.

In some embodiments, the second precursor comprises one or more of the silicon-containing precursors, the nitrogen-containing precursors, the hydrogen-containing precursors, the oxygen-containing precursors, and the carbon-containing precursors described herein. In some embodiments, the first precursor and the second precursor are independently selected from the group consisting of the silicon-containing precursors, the nitrogen-containing precursors, the hydrogen-containing precursors, the oxygen-containing precursors, and the carbon-containing precursors described herein. In some embodiments, the first precursor and the second precursor are same. In some embodiments, the first precursor and the second precursor are different.

In some embodiments, the third precursor comprises one or more of the silicon-containing precursors, the nitrogen-containing precursors, the hydrogen-containing precursors, the oxygen-containing precursors, and the carbon-containing precursors described herein. In some embodiments, one or more of the first precursor, the second precursor and the third precursor are independently selected from the group consisting of any of the silicon-containing precursors, the nitrogen-containing precursors, the hydrogen-containing precursors, the oxygen-containing precursors, and the carbon-containing precursors described herein. In some embodiments, at least two of the first precursor, the second precursor and the third precursor are the same. In some embodiments, at least one of the first precursor, the second precursor and the third precursor is different than the remaining precursors.

In some embodiments, the precursors or derivatives thereof are volatile and thermally stable. In some embodiments, the precursors or derivatives thereof are suitable for vapor deposition.

In some embodiments, the precursor comprises a carrier gas. In some embodiments, the carrier gas comprises an inert gas. In some embodiments, the carrier gas comprises helium, argon, nitrogen or combinations thereof.

In some embodiments, the precursor comprises a reactant. In some embodiments, the reactant comprises a reducing agent, an oxidizing agent, or combinations thereof. In some embodiments, the oxidizing agent comprises oxygen (O₂), ozone (O₃), nitrous oxide (N₂O), nitrogen dioxide (NO₂), water (H₂O), carbon monoxide (CO), carbon dioxide (CO₂), or combinations thereof. In some embodiments, the reducing agent comprises hydrogen (H₂), silane (SiH₄), disilane (Si₂H₆), trisilane (Si₃H₈), tetrasilane (Si₄H₁₀), higher order silane (SiₓH_{y}), ammonia (NH₃), or combinations thereof. In some embodiments, the reactant is selected from the group consisting of oxygen (O₂), ozone (O₃), nitrous oxide (N₂O), nitrogen dioxide (NO₂), water (H₂O), carbon monoxide (CO), carbon dioxide (CO₂), ammonia (NH₃), nitrogen (N₂), hydrogen (H₂), or combinations thereof.

In some embodiments, the precursor is solid or liquid. In some embodiments, the precursor is held in an ampoule. In some embodiments, a flow of the carrier gas passes through the ampoule and brings the precursor along to a process region.

At process operation 214, the process operation 210 comprises optionally purging the substrate surface 110s. The purging can be any suitable purge process that removes unreacted precursor, reaction products and by-products from the process region adjacent to the substrate surface. The suitable purge process includes moving the substrate 110 through a gas curtain to a portion or sector of the processing region that contains none or substantially none of the reactant. In one or more embodiments, purging the processing region comprises applying a vacuum. In some embodiments, purging the processing region comprises flowing a purge gas over the substrate 110 (or substrate surface 110s). In some embodiments, the purge process comprises flowing the same inert gas that is used as the carrier gas for the precursor. In one or more embodiments, the purge gas is selected from one or more of nitrogen (N₂), helium (He), and argon (Ar).

In some embodiments, the process operation 210 is performed in the presence of a plasma. In some embodiments, the plasma comprises a high-density plasma. In some embodiments, the plasma comprises a capacitively coupled plasma (CCP). In some embodiments, the CCP is formed at a radio frequency of 13.56 MHz. In some embodiments, the plasma comprises a directional plasma. In some embodiments, the directional plasma is generated without application of a bias voltage to the substrate 110. In some embodiments, the directional plasma is generated using the substrate 110, and the substrate 110 is a self-biasing substrate.

At process operation 220, a thickness of the film coating 120, or number of process cycles 210 is considered. If the film coating 120 has reached a predetermined thickness or a predetermined number of process cycles have been performed, the method 200 moves to a process operation 230. If the thickness of the film coating 120 or the number of duty cycles has not reached the predetermined thickness threshold, the method 200 returns to the process operation 212, and continues until the predetermined thickness is achieved.

In one or more embodiments, the predetermined thickness is in a range from 1 nm to 1000 nm, from 1 nm to 800 nm, from 1 nm to 600 nm, from 1 nm to 400 nm, from 1 nm to 200 nm, from 1 nm to 100 nm, from 1 nm to 50 nm, from 50 nm to 1000 nm, from 50 nm to 800 nm, from 50 nm to 600 nm, from 50 nm to 400 nm, from 50 nm to 200 nm, from 50 nm to 100 nm, from 100 nm to 1000 nm, from 100 nm to 800 nm, from 100 nm to 600 nm, from 100 nm to 400 nm, from 100 nm to 200 nm, from 200 nm to 1000 nm, from 200 nm to 800 nm, from 200 nm to 600 nm, from 200 nm to 400 nm, from 400 nm to 1000 nm, from 400 nm to 800 nm, from 400 nm to 600 nm, from 600 nm to 1000 nm, from 600 nm to 800 nm, or from 800 nm to 1000 nm.

In one or more embodiments, the number of duty cycles is in a range from 1 to 1000, from 10 to 1000, from 100 to 1000, from 200 to 1000, from 400 to 1000, from 600 to 1000, from 800 to 1000, from 1 to 800, from 10 to 800, from 100 to 800, from 200 to 800, from 400 to 800, from 600 to 800, from 1 to 600, from 10 to 600, from 100 to 600, from 200 to 600, from 400 to 600, from 1 to 400, from 10 to 400, from 100 to 400, from 200 to 400, from 1 to 200, from 10 to 200, from 100 to 200, from 1 to 100, from 10 to 100, or from 1 to 10.

In one or more embodiments, the film coating 120 has a density in a range from 0.9 g/cm³ to 2.6 g/cm³, from 0.9 g/cm³ to 2.3 g/cm³, from 0.9 g/cm³ to 1.9 g/cm³, from 0.9 g/cm³ to 1.7 g/cm³, from 0.9 g/cm³ to 1.4 g/cm³, from 0.9 g/cm³ to 1.1 g/cm³, from 1.1 g/cm³ to 2.6 g/cm³, from 1.1 g/cm³ to 2.3 g/cm³, from 1.1 g/cm³ to 1.9 g/cm³, from 1.1 g/cm³ to 1.7 g/cm³, from 1.1 g/cm³ to 1.4 g/cm³, from 1.4 g/cm³ to 2.6 g/cm³, from 1.4 g/cm³ to 2.3 g/cm³, from 1.4 g/cm³ to 1.9 g/cm³, from 1.4 g/cm³ to 1.7 g/cm³, from 1.7 g/cm³ to 2.6 g/cm³, from 1.7 g/cm³ to 2.3 g/cm³, from 1.7 g/cm³ to 1.9 g/cm³, from 1.9 g/cm³ to 2.6 g/cm³, from 1.9 g/cm³ to 2.3 g/cm³, or from 2.3 g/cm³ to 2.6 g/cm³. In some embodiments, the film coating 120 has a density in a range from 0.9 g/cm³ to 1.9 g/cm³. In some embodiments, the film coating 120 has a density in a range from 1.9 g/cm³ to 2.6 g/cm³.

In one or more embodiments, the film coating 120 has a refractive index in a range from 1.35 to 2.2, from 1.35 to 2.0, from 1.35 to 1.80, from 1.35 to 1.65, from 1.35 to 1.5, from 1.5 to 2.2, from 1.5 to 2.0, from 1.5 to 1.8, from 1.5 to 1.65, from 1.65 to 2.2, from 1.65 to 2.0, from 1.65 to 1.8, from 1.8 to 2.2, from 1.8 to 2.0, or from 2.0 to 2.2. In some embodiments, the film coating 120 has a refractive index in a range from 1.35 to 1.5. In some embodiments, the film coating 120 has a refractive index in a range from 1.8 to 2.2.

In one or more embodiments, the film coating 120 has a water vapor transmission rate less than 0.04 g/m²/day, the water vapor transmission rate is measured at 90% relative humidity and at 37.8° C. as measured on a plastic (cyclic olefin polymer) sheet sample substrate. In one or more embodiments, the film coating 120 has a water vapor transmission rate of less than 0.006 g/m²/day, the water vapor transmission rate is measured at 90% relative humidity and at 37.8° C. as measured on a plastic (cyclic olefin polymer) sheet sample substrate. In some embodiments, the film coating 120 has a water vapor transmission rate in a range from 0.00001 to 0.04 g/m²/day, from 0.00001 to 0.02 g/m²/day, from 0.00001 to 0.01 g/m²/day, from 0.00001 to 0.008 g/m²/day, from 0.00001 to 0.006 g/m²/day, from 0.006 to 0.04 g/m²/day, from 0.006 to 0.02 g/m²/day, from 0.006 to 0.01 g/m²/day, from 0.006 to 0.008 g/m²/day, from 0.008 to 0.04 g/m²/day, from 0.008 to 0.02 g/m²/day, from 0.008 to 0.01 g/m²/day, from 0.01 to 0.04 g/m²/day, from 0.01 to 0.02 g/m²/day, or from 0.02 to 0.04 g/m²/day, and the water vapor transmission rate is measured at 90% relative humidity and at 37.8° C. as measured on a plastic (cyclic olefin polymer) sheet sample substrate.

In some embodiments, the film coating 120 has a water vapor transmission rate in a range from 0.00001 to 0.04 g/m²/day, from 0.00001 to 0.02 g/m²/day, from 0.00001 to 0.01 g/m²/day, from 0.00001 to 0.008 g/m²/day, from 0.00001 to 0.006 g/m²/day, from 0.006 to 0.04 g/m²/day, from 0.006 to 0.02 g/m²/day, from 0.006 to 0.01 g/m²/day, from 0.006 to 0.008 g/m²/day, from 0.008 to 0.04 g/m²/day, from 0.008 to 0.02 g/m²/day, from 0.008 to 0.01 g/m²/day, from 0.01 to 0.04 g/m²/day, from 0.01 to 0.02 g/m²/day, or from 0.02 to 0.04 g/m²/day, and the water vapor transmission rate is measured at 90% relative humidity and at 37.8° C., wherein the substrate is according to any of the embodiment described in this disclosure.

In some embodiments, the film coating 120 has a water vapor transmission rate in a range from 0.00001 to 0.04 g/m²/day, from 0.00001 to 0.02 g/m²/day, from 0.00001 to 0.01 g/m²/day, from 0.00001 to 0.008 g/m²/day, from 0.00001 to 0.006 g/m²/day, from 0.006 to 0.04 g/m²/day, from 0.006 to 0.02 g/m²/day, from 0.006 to 0.01 g/m²/day, from 0.006 to 0.008 g/m²/day, from 0.008 to 0.04 g/m²/day, from 0.008 to 0.02 g/m²/day, from 0.008 to 0.01 g/m²/day, from 0.01 to 0.04 g/m²/day, from 0.01 to 0.02 g/m²/day, or from 0.02 to 0.04 g/m²/day, and the water vapor transmission rate is measured at 90% relative humidity and at 37.8° C., and the substrate comprises an elastomer material according to any of the embodiments described in this disclosure.

In some embodiments, the film coating 120 has a water vapor transmission rate in a range from 0 to 0.04 g/m²/day, from 0 to 0.02 g/m²/day, from 0 to 0.01 g/m²/day, from 0 to 0.008 g/m²/day, from 0 to 0.006 g/m²/day, from 0.006 to 0.04 g/m²/day, from 0.006 to 0.02 g/m²/day, from 0.006 to 0.01 g/m²/day, from 0.006 to 0.008 g/m²/day, from 0.008 to 0.04 g/m²/day, from 0.008 to 0.02 g/m²/day, from 0.008 to 0.01 g/m²/day, from 0.01 to 0.04 g/m²/day, from 0.01 to 0.02 g/m²/day, or from 0.02 to 0.04 g/m²/day, and the water vapor transmission rate is measured at 90% relative humidity and at 37.8° C. and the substrate comprises a plastic material according to any of the embodiments described in this disclosure.

In one or more embodiments, the film coating 120 has an oxygen transmission rate less than 30 cc/m²/day, and the oxygen transmission rate is measured at 50% relative humidity and at 37.8° C. In one or more embodiments, the film coating 120 has an oxygen transmission rate of less than 0.4 cc/m²/day, and the oxygen transmission rate is measured at 50% relative humidity and at 37.8° C. In some embodiments, the film coating 120 has an oxygen transmission rate in a range from 0.01 to 30 cc/m²/day, from 0.01 to 25 cc/m²/day, from 0.01 to 20 cc/m²/day, from 0.01 to 15 cc/m²/day, from 0.01 to 10 cc/m²/day, from 0.01 to 5 cc/m²/day, from 0.01 to 1 cc/m²/day, from 0.01 to 0.4 cc/m²/day, from 0.4 to 30 cc/m²/day, from 0.4 to 25 cc/m²/day, from 0.4 to 20 cc/m²/day, from 0.4 to 15 cc/m²/day, from 0.4 to 10 cc/m²/day, from 0.4 to 5 cc/m²/day, from 0.4 to 1 cc/m²/day, from 1 to 30 cc/m²/day, from 1 to 25 cc/m²/day, from 1 to 20 cc/m²/day, from 1 to 15 cc/m²/day, from 1 to 10 cc/m²/day, from 1 to 5 cc/m²/day, from 5 to 30 cc/m²/day, from 5 to 25 cc/m²/day, from 5 to 20 cc/m²/day, from 5 to 15 cc/m²/day, from 5 to 10 cc/m²/day, from 10 to 30 cc/m²/day, from 10 to 25 cc/m²/day, from 10 to 20 cc/m²/day, from 10 to 15 cc/m²/day, from 15 to 30 cc/m²/day, from 15 to 25 cc/m²/day, from 15 to 20 cc/m²/day, from 20 to 30 cc/m²/day, from 20 to 25 cc/m²/day, or from 25 to 30 cc/m²/day, and the oxygen transmission rate is measured at 50% relative humidity and at 37.8° C. as measured on a plastic (cyclic olefin polymer) sheet sample substrate.

In some embodiments, the film coating 120 has an oxygen transmission rate in a range from 0.01 to 30 cc/m²/day, from 0.01 to 25 cc/m²/day, from 0.01 to 20 cc/m²/day, from 0.01 to 15 cc/m²/day, from 0.01 to 10 cc/m²/day, from 0.01 to 5 cc/m²/day, from 0.01 to 1 cc/m²/day, from 0.01 to 0.4 cc/m²/day, from 0.4 to 30 cc/m²/day, from 0.4 to 25 cc/m²/day, from 0.4 to 20 cc/m²/day, from 0.4 to 15 cc/m²/day, from 0.4 to 10 cc/m²/day, from 0.4 to 5 cc/m²/day, from 0.4 to 1 cc/m²/day, from 1 to 30 cc/m²/day, from 1 to 25 cc/m²/day, from 1 to 20 cc/m²/day, from 1 to 15 cc/m²/day, from 1 to 10 cc/m²/day, from 1 to 5 cc/m²/day, from 5 to 30 cc/m²/day, from 5 to 25 cc/m²/day, from 5 to 20 cc/m²/day, from 5 to 15 cc/m²/day, from 5 to 10 cc/m²/day, from 10 to 30 cc/m²/day, from 10 to 25 cc/m²/day, from 10 to 20 cc/m²/day, from 10 to 15 cc/m²/day, from 15 to 30 cc/m²/day, from 15 to 25 cc/m²/day, from 15 to 20 cc/m²/day, from 20 to 30 cc/m²/day, from 20 to 25 cc/m²/day, or from 25 to 30 cc/m²/day, and the oxygen transmission rate is measured at 50% relative humidity and at 37.8° C. and the substrate is according to any of the embodiments described in this disclosure.

In some embodiments, the film coating 120 has an oxygen transmission rate in a range from 0.01 to 30 cc/m²/day, from 0.01 to 25 cc/m²/day, from 0.01 to 20 cc/m²/day, from 0.01 to 15 cc/m²/day, from 0.01 to 10 cc/m²/day, from 0.01 to 5 cc/m²/day, from 0.01 to 1 cc/m²/day, from 0.01 to 0.4 cc/m²/day, from 0.4 to 30 cc/m²/day, from 0.4 to 25 cc/m²/day, from 0.4 to 20 cc/m²/day, from 0.4 to 15 cc/m²/day, from 0.4 to 10 cc/m²/day, from 0.4 to 5 cc/m²/day, from 0.4 to 1 cc/m²/day, from 1 to 30 cc/m²/day, from 1 to 25 cc/m²/day, from 1 to 20 cc/m²/day, from 1 to 15 cc/m²/day, from 1 to 10 cc/m²/day, from 1 to 5 cc/m²/day, from 5 to 30 cc/m²/day, from 5 to 25 cc/m²/day, from 5 to 20 cc/m²/day, from 5 to 15 cc/m²/day, from 5 to 10 cc/m²/day, from 10 to 30 cc/m²/day, from 10 to 25 cc/m²/day, from 10 to 20 cc/m²/day, from 10 to 15 cc/m²/day, from 15 to 30 cc/m²/day, from 15 to 25 cc/m²/day, from 15 to 20 cc/m²/day, from 20 to 30 cc/m²/day, from 20 to 25 cc/m²/day, or from 25 to 30 cc/m²/day, and the oxygen transmission rate is measured at 50% relative humidity and at 37.8° C. and the substrate comprises the elastomer material according to any of the embodiments described in this disclosure.

In some embodiments, the film coating 120 has an oxygen transmission rate in a range from 0.01 to 30 cc/m²/day, from 0.01 to 25 cc/m²/day, from 0.01 to 20 cc/m²/day, from 0.01 to 15 cc/m²/day, from 0.01 to 10 cc/m²/day, from 0.01 to 5 cc/m²/day, from 0.01 to 1 cc/m²/day, from 0.01 to 0.4 cc/m²/day, from 0.4 to 30 cc/m²/day, from 0.4 to 25 cc/m²/day, from 0.4 to 20 cc/m²/day, from 0.4 to 15 cc/m²/day, from 0.4 to 10 cc/m²/day, from 0.4 to 5 cc/m²/day, from 0.4 to 1 cc/m²/day, from 1 to 30 cc/m²/day, from 1 to 25 cc/m²/day, from 1 to 20 cc/m²/day, from 1 to 15 cc/m²/day, from 1 to 10 cc/m²/day, from 1 to 5 cc/m²/day, from 5 to 30 cc/m²/day, from 5 to 25 cc/m²/day, from 5 to 20 cc/m²/day, from 5 to 15 cc/m²/day, from 5 to 10 cc/m²/day, from 10 to 30 cc/m²/day, from 10 to 25 cc/m²/day, from 10 to 20 cc/m²/day, from 10 to 15 cc/m²/day, from 15 to 30 cc/m²/day, from 15 to 25 cc/m²/day, from 15 to 20 cc/m²/day, from 20 to 30 cc/m²/day, from 20 to 25 cc/m²/day, or from 25 to 30 cc/m²/day, and the water vapor transmission rate is measured at 90% relative humidity and at 37.8° C. as measured on plastic sheets and the substrate comprises the plastic material according to any of the embodiments described in this disclosure.

A lubricity/surface roughness of the film can be measured by any of the known techniques known to a person skilled in the art. In some embodiments, the lubricity/surface roughness is measured by dynamic coefficient of friction test. In some embodiments, the second layer has a coefficient of friction less than 0.4, less than 0.3, less than 0.2 or less than 0.1. In some embodiments, the second layer has a coefficient of friction in a range from more than 0 to less than 0.4, from more than 0 to less than 0.3, from more than 0 to less than 0.2, from more than 0 to less than 0.1, from more than 0.1 to less than 0.4, from more than 0.1 to less than 0.3, from more than 0.1 to less than 0.2, from more than 0.2 to less than 0.4, from more than 0.2 to less than 0.3, or from more than 0.3 to less than 0.4.

In some embodiments, the third layer has a coefficient of friction less than 0.4, less than 0.3, less than 0.2, or less than 0.1. In some embodiments, the third layer has a coefficient of friction in a range from more than 0 to less than 0.4, from more than 0 to less than 0.3, from more than 0 to less than 0.2, from more than 0 to less than 0.1, from more than 0.1 to less than 0.4, from more than 0.1 to less than 0.3, from more than 0.1 to less than 0.2, from more than 0.2 to less than 0.4, from more than 0.2 to less than 0.3, or from more than 0.3 to less than 0.4.

An extractability/leachability of the film coating can be measured by any of the known techniques known to a person skilled in the art. In some embodiments, the extractability/leachability of the film coating 120 is measured by determining release of contaminants across the film coating 120. In some embodiments, the release of contaminants is determined by using Gas/Liquid chromatography (GCMS/LCMS). In some embodiments, the film coating 120 reduces the release of contaminants more than 20%, more than 40%, more than 60% or more than 80% as compared to packaging material that does not include a film coating. In some embodiments, the film coating 120 reduces the release of contaminants in a range from 20% to less than 100%, from 20% to less than 80%, from 20% to less than 60%, from 20% to less than 40%, from 40% to less than 100%, from 40% to less than 80%, from 40% to less than 60%, from 60% to less than 100%, from 60% to less than 80%, or from 80% to less than 100% compared to packaging material that does not include a film coating. In some embodiments, for example, when the substrate comprises butyl rubber, the film coating 120 reduces the release of contaminants by more than 20%, more than 40%, more than 60%, or more than 80%, as compared to packaging material that does not include a film coating. Similarly, in other embodiments when the substrate comprises butyl rubber, the film coating 120 reduces the release of contaminants in a range from 20% to less than 100%, from 20% to less than 80%, from 20% to less than 60%, from 20% to less than 40%, from 40% to less than 100%, from 40% to less than 80%, from 40% to less than 60%, from 60% to less than 100%, from 60% to less than 80%, or from 80% to less than 100%, as compared to packaging material that does not include a film coating.

In one or more embodiments, the precursor comprises a plurality of precursors. In some embodiments, the plurality of precursors comprises at least two precursors. In some embodiments, the at least two precursors further comprise a third precursor. In some embodiments, all of the plurality of precursor are the same. In other embodiments, all of the plurality of precursors are different from each other. In yet other embodiments, at least one of the plurality of precursors is different than the remaining precursor(s).

In one or more embodiments, the operation 210 is repeated at least one more time to deposit the plurality of layers. In one or more embodiments, the substrate 110 (or substrate surface) is sequentially exposed to a plurality of precursors to deposit the plurality of layers.

In some embodiments, the film coating 120 has a coefficient of friction in a range from more than 0 to less than 0.4. In some embodiments, the second layer 140 has a coefficient of friction in a range from more than 0 to less than 0.4. In some embodiments, the third layer 150 has a coefficient of friction in a range from more than 0 to less than 0.4.

At operation 230, the number of layer(s) is considered. If the film coating 120 has a predetermined number of layer(s), the method 200 moves to an optional post-processing operation 250. If the film coating 120 does not have the predetermined number of layer(s), the method 200 returns to operation 210, and continues to operation 220. In some embodiments, the predetermined number is more than one, more than two or more than three. In some embodiments, the predetermined number is at least two or at least three. In some embodiments, the predetermined number is a positive integer. In some embodiments, the predetermined number of layers is two. In some embodiments, the predetermined number is three.

In some embodiments, the film coating 120 reduces the release of contaminants by more or equal to 20%. In some embodiments, the film coating 120 reduces the release of contaminants in a range from 20% to less than 100%.

The optional post-processing operation 250 can be, for example, a process to modify film properties (e.g., annealing) or a further film deposition process (e.g., additional ALD or CVD processes) to grow additional films. In some embodiments, the optional post-processing operation 230 can be a process that modifies a property of the deposited film. In some embodiments, the optional post-processing operation 230 comprises annealing the as-deposited film coating. In some embodiments, annealing is done at temperatures in the range from about 250° C. to about 300° C., to about 400° C., to about 500° C., to about 600° C., to about 700° C., to about 800° C., to about 900° C. or to about 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film coating is annealed for a predetermined time in the range from about 15 seconds to about 90 minutes, or in the range from about 1 minute to about 60 minutes. In some embodiments, annealing the as-deposited film coating increases the density, decreases the resistivity and/or increases the purity of the film coating.

In one or more embodiments, the disclosure provides a two-layer film coating on a substrate, the substrate comprising vials/syringes, with the film coating providing one or more of drug inertness, lubricity and superior barrier performance. In some embodiments, the two-layer film coating comprises a hexamethyldisiloxane layer and a silane layer. In some embodiments, the silane layer sandwiches the hexamethyldisiloxane layer between the substrate and the silane layer. In some embodiments, the two-layer film coating comprises a hexamethyldisiloxane layer and a silane layer. In some embodiments, the hexamethyldisiloxane layer and the silane layer are deposited on the vials/syringes according to any of the embodiments described in this disclosure. In some embodiments, the two-layer coated vial/syringe has a lubricity equal or better than that of silicone oil.

In one or more embodiments, the disclosure provides a two-layer film coating on a substrate, and the substrate comprises elastomeric stoppers and syringe plungers, with the film coating providing one or more of improved barrier, reduced extractables & leachables and having a more lubricious surface (e.g., for plungers). In some embodiments, the two-layer film coating comprises a hexamethyldisiloxane layer and a silane layer. In some embodiments, a hexamethyldisiloxane layer is sandwiched between the silane layer and the substrate. In some embodiments, the hexamethyldisiloxane layer and the silane layer are deposited on the elastomeric stoppers and/or syringe plungers according to any of the embodiments described in this disclosure. In some embodiments, a two-layer coated elastomeric stopper meets a closure-container seal integrity according to a helium (He) leak test specification. In some embodiments, a two-layer coated syringe plunger has a lubricity equal to or better than that of silicone oil.

In one or more embodiments, the disclosure provides a three-layer film coating on a substrate, the substrate comprising vials/syringes, with the film coating providing one or more of drug inertness, lubricity and superior barrier performance. In some embodiments, the three-layer film coating comprises an adhesion layer, a hexamethyldisiloxane layer and a silane layer. In some embodiments, the adhesion layer, the hexamethyldisiloxane layer and the silane layer are stacked on the substrate. In some embodiments, the silane layer and the substrate sandwiches the adhesion layer and the hexamethyldisiloxane layer. In some embodiments, the substrate and the hexamethyldisiloxane layer sandwiches the adhesion layer. In some embodiments, the silane layer and the hexamethyldisiloxane layer sandwiches the adhesion layer. In some embodiments, the adhesion layer, the hexamethyldisiloxane layer and the silane layer are deposited on the vials/syringes according to any of the embodiments described in this disclosure. In some embodiments, the three-layer coated vial/syringe has a lubricity equal or better than that of silicone oil.

In one or more embodiments, the disclosure provides applying a three-layer film coating on a substrate, and the substrate comprises elastomeric stoppers and syringe plungers, with the film coating providing one or more of improved barrier, reduced extractables & leachables and having a more lubricious surface (e.g., for plungers). In some embodiments, the three-layer film coating comprises an adhesion layer, a hexamethyldisiloxane layer and a silane layer. In some embodiments, the silane layer and the substrate sandwiches the adhesion layer and the hexamethyldisiloxane layer. In some embodiments, the substrate and the hexamethyldisiloxane layer sandwiches the adhesion layer. In some embodiments, the silane layer and the hexamethyldisiloxane layer sandwiches the adhesion layer. In some embodiments, the adhesion layer, the hexamethyldisiloxane layer and the silane layer are deposited on the elastomeric stoppers and/or syringe plungers according to any of the embodiments described in this disclosure. In some embodiments, a three-layer coated elastomeric stopper meets a closure-container seal integrity according to a helium (He) leak test specification. In some embodiments, a three-layer coated syringe plunger has a lubricity equal to or better than that of silicone oil.

In one or more embodiments, one or more of the hexamethyldisiloxane precursor and the silane precursor are volatile and thermally stable, and, thus, suitable for vapor deposition. In some embodiments, one or more of the hexamethyldisiloxane precursor and the silane precursor are deposited by a vapor deposition technique. In some embodiments, the vapor depositing technique comprises a chemical vapor deposition (CVD).

In one or more embodiments, the method 200 comprises a chemical vapor deposition (CVD) method, a plasma-enhanced chemical vapor deposition (PE-CVD) method, a high density plasma chemical vapor deposition (HDPCVD) method, a microwave chemical vapor deposition (microwave CVD) method, an atomic layer deposition (ALD) method, a plasma-enhanced atomic layer deposition (PE-ALD) method or a combination thereof.

The method can further be adopted to deposit one or more additional functional coatings. In some embodiments, the additional functional coating comprises an adhesion layer. In some embodiments, the adhesion layer advantageously improves adhesion of the film coating to the substrate 110. In some embodiments, the adhesion layer is configured to act as an oxygen barrier and/or a water barrier. In some embodiments, the additional functional coating is configured to meet future requirements for pharmaceutical packaging. The future requirements include, but are not limited to, increasing adoption of cell/gene therapy drugs.

In some embodiments, the packaging material 100 is stable during sterilization process. The sterilization process includes, but is not limited to, autoclaving, plasma treatment, electron beam irradiation, gamma irradiation, ethylene dioxide treatment or combinations thereof. In some embodiments, autoclaving comprises wet sterilization cycle and dry sterilization cycle. The wet sterilization process includes sterilizing at a temperature of 121° C. for a time period of 30 minutes. The dry sterilization process includes sterilizing at a temperature of 150° C. for a time period of 150 minutes, a temperature of 160° C. for a time period of 120 minutes or a temperature of 170° C. for a time period of 60 minutes.

In one or more embodiments, the method 200 is performed under vacuum, for example, in a substrate processing chamber. The method 200 can be performed in any vacuum platform based system. In one or more embodiments, the substrate is brought in an array of individual units or in a bank or panel format inside a vacuum chamber. In one or more embodiments, the method is performed in a substrate processing chamber such as a chemical vapor deposition (CVD) substrate processing chamber, a plasma-enhanced chemical vapor deposition (PE-CVD) substrate processing chamber, a high density plasma chemical vapor deposition (HDPCVD) substrate processing chamber, a microwave chemical vapor deposition (microwave CVD) substrate processing chamber, an atomic layer deposition (ALD) substrate processing chamber, and a plasma-enhanced atomic layer deposition (PE-ALD) substrate processing chamber.

In one or more embodiments, the method 200 advantageously provides a cleaner and/or more sterile environment for pharmaceutical packaging operations. In some embodiments, the method 200 advantageously eliminates a need of sterilization treatment that is needed in the downstream process flow. In some embodiments, the method 200 is performed in the presence of a high-density plasma. According to one or more embodiments, the high-density plasma can be used to sterilize parts of coating. The sterilization process using the high-density plasma is in compliance with and used to shorten pharma package manufacturing flow.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Example ranges for the various parameters described herein represent exemplary ranges based upon current experiments and/or modeling. Other ranges than these exemplary ranges may be contemplated within the scope of this disclosure. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification is not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A packaging material, the packaging material comprising:
a substrate including a substrate surface, the substrate surface comprising a material selected from the group consisting of an elastomer, a polymer, an inorganic material and combinations thereof; and
a film coating comprising a first layer on the substrate surface and a second layer on the first layer, wherein the first layer comprises a first material having a formula of SiOₓN_{y}C_{z}, where x is in a range from 1.9 to 2.15, y is in a range from 0.01 to 0.08, and z is in a range from 0.10 to 0.40, and the second layer comprises a second material having a formula of SiOₓN_{y}C_{z}, where x is in a range from 1.30 to 1.50, y is in a range from 0.05 to 0.20, and z is in a range from 1 to 2.

2. The packaging material of claim 1, wherein the packaging material is selected from the group consisting of a vial, a syringe, a bottle, a cartridge, an ampoule, an injection pen, a patch, a blister pack and an intravenous infusion bag.

3. The packaging material of claim 1, wherein the substrate surface comprises a glass, an elastomer, a polymer or a combination thereof.

4. The packaging material of claim 1, wherein each of the first layer and the second layer independently has a thickness in a range from 1 nm to 1000 nm.

5. The packaging material of claim 1, wherein the film coating has one or more properties selected from the group consisting of a water vapor transmission in a range from 0.00001 g/m²/day to less than 0.04 g/m²/day at 37.8° C. and 90% relative humidity, and an oxygen transmission rate in a range from 0.01 cc/m²/day to less than 30 cc/m²/day at 37.8° C. and 50% relative humidity.

6. The packaging material of claim 1, wherein the film coating has one or more properties selected from the group consisting of water vapor transmission less than 0.006 g/m²/day as measured at 90% relative humidity and 37.8° C. and an oxygen transmission rate less than 0.4 cc/m²/day as measured at 50% relative humidity and 37.8° C.

7. The packaging material of claim 1, wherein the second layer has a coefficient of friction in a range from more than 0 to less than 0.40.

8. The packaging material of claim 1, wherein the film coating comprises a third layer on the second layer, and the third layer comprises a material having a formula of SiH_{w}OₓN_{y}, where w is in a range from 0.01 to 1.1, x is in a range from 0.01 to 2.3 and y is in a range from 0.01 to 1.0.

9. The packaging material of claim 8, wherein each of the first layer, the second layer and the third layer has a thickness in a range from 1 nm to 1000 nm.

10. The packaging material of claim 8, wherein the third layer has a coefficient of friction in a range from more than 0 to less than 0.40.

11. The packaging material of claim 8, wherein the film coating reduces leachability/extractability in a range from more than 20% to less than 100% compared to a packaging material that does not have a coating.

12. The packaging material of claim 8, wherein the film coating has one or more properties selected from the group consisting of a water vapor transmission in a range from 0 g/m²/day to less than 0.04 g/m²/day at 37.8° C. and 90% relative humidity, and an oxygen transmission rate in a range from 0 30 cc/m²/day to less than 30 cc/m²/day at 37.8° C. and 50% relative humidity.

13. The packaging material of claim 8, wherein the film coating further comprises one or more additional layers between the second layer and the third layer, the one or more additional layers has a thickness in a range from 1 nm to 100 nm, and the one or more additional layers independently comprises a formula of SiOₓN_{y}C_{z}, where x is in a range from 1.30 to 1.50, y is in a range from 0.05 to 0.20, and z is in a range from 1 to 2, or a formula of SiH_{w}OₓN_{y}, where w is in a range from 0.01 to 1.1, x is in a range from 0.01 to 2.3 and y is in a range from 0.01 to 1.0.

14. A method of depositing a film coating on a packaging material comprising a substrate surface, the method comprising:
exposing the substrate surface to a first precursor to deposit a first layer on the substrate surface, the first layer having a formula of SiOₓN_{y}C_{z}, where x is in a range from 1.9 to 2.15, y is in a range from 0.01 to 0.08, and z is in a range from 0.10 to 0.40;
optionally purging the first precursor; and
exposing the first layer to a second precursor to deposit a second layer on the first layer, the second layer having a formula of SiOₓN_{y}C_{z}, where x is in a range from 1.30 to 1.50, y is in a range from 0.05 to 0.20, and z is in a range from 1.0 to 2.0,
wherein each of the first precursor and the second precursor independently comprises a silicon-containing precursor selected from the group consisting of SiH₄, SiF₄, Si₂H₆ or a combination thereof, a nitrogen-containing precursor selected from a group consisting of ammonia (NH₃), nitrous oxide (N₂O), nitric oxide (NO), nitrogen gas (N₂) and combinations thereof, a carbon-containing precursor selected from the group consisting of acetylene (C₂H₂), ethane (C₂H₆), ethene (C₂H₄), methane (CH₄), propylene (C₃H₆), propyne (C₃H₄), propane (C₃H₈), butane (C₄H₁₀), butylene (C₄H₈), butadiene (C₄H₆), benzene (C₆H₆), toluene (C₇H₃), and hexamethyldisiloxane (C₆H₁₈OSi₂) and combinations thereof, or combinations of the silicon-containing precursor, the nitrogen-containing precursor and the carbon-containing precursor.

15. The method of claim 14, wherein the substrate surface is exposed to the first precursor until the first layer having a thickness in a range from 1 nm to 1000 nm.

16. The method of claim 14, wherein the substrate surface is exposed to the second precursor until the second layer has a thickness in a range from 1 nm to 1000 nm.

17. The method of claim 14, wherein each of the first precursor and the second precursor independently comprises a reactant, the reactant selected from the group consisting of oxygen (O₂), ozone (O₃), nitrous oxide (N₂O), nitrogen dioxide (NO₂), water (H₂O), carbon monoxide (CO), carbon dioxide (CO₂), ammonia (NH₃), nitrogen (N₂), hydrogen (H₂) or combinations thereof.

18. The method of claim 14, further comprising optionally purging the second precursor, and exposing the second layer to a third precursor to deposit a third layer, the third precursor comprising a silicon-containing precursor, a nitrogen-containing precursor, a hydrogen-containing precursor, an oxygen-containing precursor, a carbon-containing precursor or combinations thereof.

19. The method of claim 18, wherein the substrate surface is exposed to the third precursor until the third layer has a thickness in a range from 1 nm to 1000 nm.

20. The method of claim 18, wherein each of the first precursor, the second precursor and the third precursor independently comprises a reactant, the reactant is selected from the group consisting of oxygen (O₂), ozone (O₃), nitrous oxide (N₂O), nitrogen dioxide (NO₂), water (H₂O), carbon monoxide (CO), carbon dioxide (CO₂), ammonia (NH₃), nitrogen (N₂), hydrogen (H₂) or combinations thereof.
